(19) United States
(12) Patent Application Publication
(10) Pub. No.: US 2011/0308572 A1
(43) Pub. Date: Dec. 22, 2011

(54) Solar collector optics

(75) Inventor: Ronald O. Woodward, Yorktown, VA (US)

(73) Assignee: Magna International Inc., Aurora (CA)

(21) Appl. No.: 13/134,750

(22) Filed: Jun. 16, 2011

Related U.S. Application Data
(60) Provisional application No. 61/397,870, filed on Jun. 17, 2010.

(51) Int. Cl. H01L 31/052; B29D 11/00; G02B 3/00; B23P 17/04; G02B 5/04

(52) U.S. Cl. 136/246; 29/592; 359/831; 359/737; 264/1.7

(57) ABSTRACT

A solar collector optic system having a plurality of optics and a plurality of concentrators, where the plurality of optics directs light to the plurality of concentrators. The system has a first optic, a second optic, a first concentrator and a second concentrator. Each optic has a plurality of prisms which provide a progressive light distribution function such that as each of the plurality of prisms of the first optic is located further away from a focal line of the first concentrator, each of the plurality of prisms directs a greater amount of light to the second concentrator compared to the first concentrator. Also, as each of the plurality of prisms of the second optic is located further away from a focal line of the second concentrator, each of the plurality of prisms directs a greater amount of light to the first concentrator compared to the second concentrator.

### CROSS-REFERENCE TO RELATED APPLICATIONS

This application claims priority to U.S. Provisional Application No. 61/397,870 filed on Jun. 17, 2010. The disclosure of the above application is incorporated herein by reference.

### FIELD OF THE INVENTION

The present invention relates to a solar collector optics system which is efficient and provides a high concentration factor.

### BACKGROUND OF THE INVENTION

Current solar power optics systems which function to also concentrate light are complex and costly to manufacture. These solar power optics systems are typically composed of a large molded reflector protected by a clear cover optic concentrating light on a glass optic. Many of these solar power optics systems also incorporate what is referred to as a “concentration factor.” The concentration factor is the amount or ratio in which the light passing through the system is concentrated and directed to a light receiving device, such as a photocell. The higher the concentration factor, the greater amount of energy can be harnessed from the light passing through the system.

Some of the solar power optics systems use fresnel optic systems, which are simple to combine with the cover plate. However, these types of systems suffer significant losses in efficiency as the concentration factor increases. To increase the concentration factor, the draft angle used during the molding of the fresnel lens is changed. However, the required draft angle for molding and the loss of efficiency with high angle refraction reduce overall efficiency. Area efficiency of the fresnel optic is also decreased as the concentration factor is increased.

Accordingly, there exists a need for a solar power optics system which is highly efficient, and also has a high concentration factor.

### SUMMARY OF THE INVENTION

The present invention is a solar collector optic system having a plurality of optics and a plurality of concentrators, where the plurality of optics directs light to the plurality of concentrators.

In one embodiment, the present invention has a first fresnel optic and a second fresnel optic, and a first concentrator which is part of a first row of concentrators, and a second concentrator which is part of a second row of concentrators. The first concentrator has a focal line extending through a portion of the first optic, and the second concentrator has a focal line extending through a portion of the second optic. A row of concentrators and one of the optics make up an array. In one embodiment, there are four arrays, but it is within the scope of the invention that more or less arrays maybe used.

Each optic has a plurality of prisms which has a progressive light distribution function. Both the first optic and the second optic are formed with one or more of the plurality of prisms, such that as each of the plurality of prisms of the first optic is located further away from the focal line of the first concentrator, each of the plurality of prisms directs a greater amount of light to the second concentrator compared to the first concentrator. Also, as each of the plurality of prisms of the second optic is located further away from the focal line of the second concentrator, each of the plurality of prisms directs a greater amount of light to the first concentrator compared to the second concentrator. Each optic functions to concentrate light prior to the light entering a concentrator, and each concentrator further concentrates the light, and directs the light to a photocell.

The cost of manufacturing the solar collector optics system of the present invention is reduced by creating an extruded optic made up of several fresnel optics that concentrate light in one direction. Each fresnel optic used in the system of the present invention maintains high area and optical efficiency by concentrating light in adjacent focal lines. The fresnel optics are specifically shaped to direct light that would be lost in a standard fresnel optic to the adjacent focal line where the light is collected by the photocells in an adjacent array. The line of concentrated light is further concentrated by a secondary optic or concentrator to reach the desired 2000:1 or 2500:1 system concentration.

Accordingly, it is an object of the invention to develop a lower cost solar concentrator system that can achieve high concentration factors in the 2000:1 range or 2500:1 range, while maintaining good area efficiency.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a perspective view of solar collector optic system, according to the present invention;

FIG. 2 is a front view of a portion of a solar collector optic system, according to the present invention; and

FIG. 3 is a side view of a concentrator used as part of a solar collector optic system, according to the present invention.

### DETAILED DESCRIPTION OF THE PREFERRED EMBODIMENTS

The following description of the preferred embodiment(s) is merely exemplary in nature and is in no way intended to limit the invention, its application, or uses.

Referring to the Figures generally, a solar collector optic system is shown generally at 10. The system 10 has an optic 12 spaced at a distance 14 from a plurality of concentrators, shown generally at 16. In this embodiment, there are four rows of concentrators 16A,16B,16C,16D. There is also a plurality of photocells 18, with one photocell 18 being used to collect light from each of the concentrators 16.

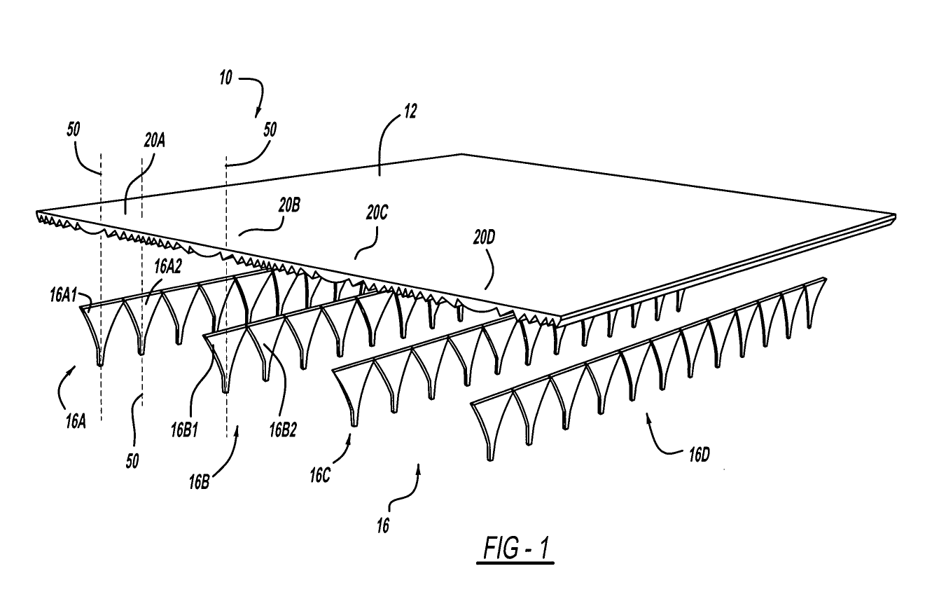

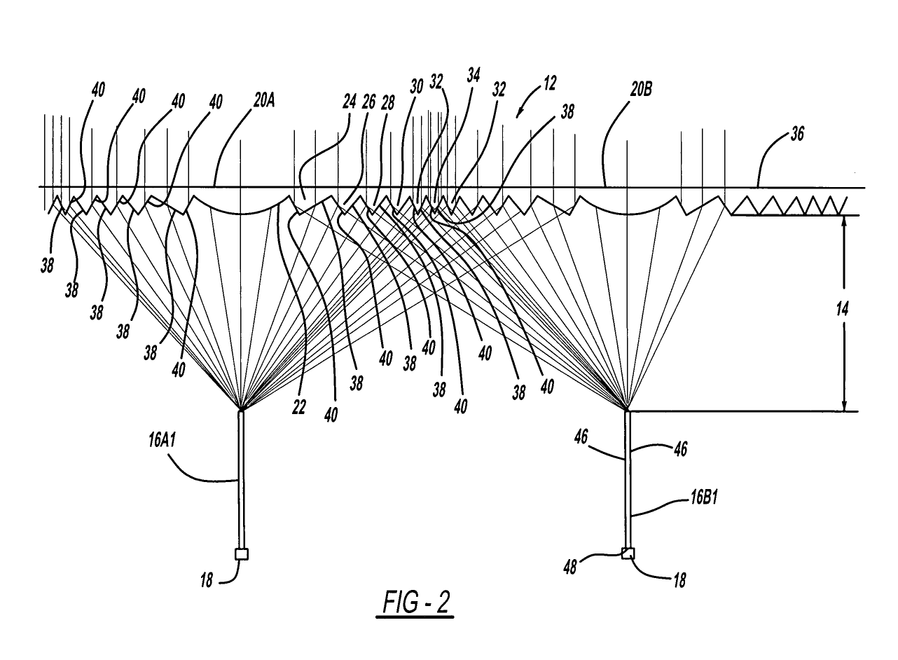

The optic 12 is made up of a plurality of fresnel optics 20 either formed separately and placed adjacent one another, or integrally molded together as shown in FIGS. 1 and 2. In this embodiment, there are four fresnel optics 20A,20B,20C,20D, but it is within the scope of the invention that more or less fresnel optics 20 may be used. A fresnel optic 20 and a row of concentrators 16 make up an array which is used to concentrate the light entering the fresnel optics 20. In this embodiment, there are four arrays as shown in FIG. 1 which are adjacent one another, but it is within the scope of the invention that more or less arrays may be used.

The optic 20 has at least one arcuate portion or arcuate elongate central portion 22, and a set of prisms having a plurality of prism elements. More specifically, each fresnel optic 20A,20B,20C,20D has an arcuate portion 22, and on each side of the arcuate portion 22 is a plurality of stepped portions or prisms. Each of the fresnel optics 20A,20B,20C,20D is substantially similar, therefore, the first fresnel optic 20A only will be described. With reference to the first fresnel optic 20A, there is a first plurality of prisms on the left side of the arcuate portion 22, and a second plurality of prisms on the right side of the arcuate portion 22. The first plurality of prisms and the second plurality of prisms are substantially mirror images of each other, making the fresnel optic 20A substantially symmetrical.

In further regard to the first plurality of prisms, there is a first prism 24 integrally formed with the arcuate portion 22 and a second prism 26, and the second prism 26 is also integrally formed with a third prism 28. The third prism 28 is integrally formed with a fourth prism 30, and the fourth prism 30 is integrally formed with a fifth prism 32. The fifth prism 32 is integrally formed with a sixth prism 34, but the sixth prism 34 is also part of the adjacent fresnel optic 20. The arcuate portion 22 and each of the prisms 24,26,28,30,32,34 focus light entering the optic 20 through an input surface 36 formed as part of the fresnel optic 20.

Light entering the input surface 36 passes through the optic 20 and exits out of either of the arcuate portion 22 or the prisms 24,26,28,30,32,34. Each prism 24,26,28,30,32,34 has an arcuate surface 38 and a substantially straight surface 40, however, the shape of these surfaces 38,40 varies, depending upon the shape of the respective prism 24,26,28,30,32,34.

With specific reference to FIG. 2, there are two concentrators 16 shown (a first concentrator 16A1 from the first row of concentrators 16A, and a second concentrator or adjacent concentrator 16B1 from the second row of concentrators 16B), with each having a photocell 18, and two fresnel optics (the first fresnel optic 20A and the second or adjacent fresnel optic 20B) integrally formed with one another such that the sixth prism 34 forms a part of each fresnel optic 20 (the straight surface 40 and the arcuate surface 30 of the sixth prism 34 are substantially the same shape, the function of which will be described later). Each concentrator 16 has an input surface 42, and each fresnel optic 20A,20B is shaped to direct light toward the input surfaces 42 of each concentrator 16 in one or more of the rows of concentrators 16A,16B,16C,16D.

More specifically, a portion of light from each arcuate portion 22 and a portion of light from each prism 24,26,28,30,32,34 is directed to each of the concentrators 16A1,16B1. The amount of light directed to the concentrators 16A1,16B1 from the arcuate portion 22 and the prisms 24,26,28,30,32,34 depends upon the shape of the arcuate portion 22 and the shape of each prism 24,26,28,30,32,34. The first fresnel optic 20A is designed such that the further the prism is away from the arcuate portion 22 (when looking at FIG. 2), the more of the light from the first fresnel optic 20A is directed towards the second concentrator 16B1. This makes the light distribution by the prisms 24,26,28,30,32,34 progressive, producing a progressive light distribution function.

Each row of concentrators 16A,16B,16C,16D extends the length of the optic 20, and therefore, the light exiting from each of the fresnel optics 20A,20B,20C,20D enters the input surfaces 42 of the concentrators 16. The light received by the input surfaces 42 depends upon the location of each concentrator 16. By way of example and with reference to the prisms 24,26,28,30,32,34 on the right-hand side of the first fresnel optic 20A shown in FIG. 2, in this embodiment substantially all of the light produced by the arcuate portion 22 of the first fresnel optic 20A is received by the input surface 42 of each concentrator 16 in the first row of concentrators 16A. Furthermore, light from the first prism 24 is substantially directed towards the input surface 42 of each concentrator 16 in the first row of concentrators 16A shown in FIG. 2, but some of the light from the first prism 24 of the first fresnel optic 20A is directed to the input surface 42 of the concentrators 16 in the second row of concentrators 16B. Each prism 24,26,28,30,32,34 on the right-hand side of the first fresnel optic 20A shown in FIG. 2 directs light to the input surfaces 42 of each concentrator 16 in the first row of concentrators 16A or the concentrators 16 in the second row of concentrators 16B, depending upon the shape of the prisms 24,26,28,30,32,34.

For example, in this embodiment, ninety-five percent of the light from the first prism 24 of the first fresnel optic 20A is directed to the input surface 42 of each concentrator 16 in the first row of concentrators 16A, and five percent of the light from the first prism 24 of the first fresnel optic 20A is directed to the input surface 42 of each concentrator 16 in the second row of concentrators 16B.

Furthermore, ninety percent of the light from the second prism 26 of the first fresnel optic 20A is directed to each input surface 42 in the first row of concentrators 16A, and ten percent of the light from the second prism 26 of the first fresnel optic 20A is directed to each input surface 42 of the second row of concentrators 16B. Eighty percent of the light from the third prism 28 of the first fresnel optic 20A is directed to each input surface 42 of the first row of concentrators 16A, and twenty percent of the light from the third prism 28 of the first fresnel optic 20A is directed to each input surface 42 of the second row of concentrators 16B. Seventy percent of the light from the fourth prism 30 of the first fresnel optic 20A is directed to each input surface 42 of the first row of concentrators 16A, and thirty percent of the light from the fourth prism 30 of the first fresnel optic 20A is directed to each input surface 42 of the second row of concentrators 16B. Sixty percent of the light from the fifth prism 32 of the first fresnel optic 20A is directed to each input surface 42 of the first row of concentrators 16A, and forty percent of the light from the fifth prism 32 of the first fresnel optic 20A is directed to each input surface 42 of the second row of concentrators 16B.

Fifty percent of the light from the sixth prism 34 of the first fresnel optic 20A is directed to each input surface 42 of the first row of concentrators 16A, and fifty percent of the light from the sixth prism 34 of the first fresnel optic 20A is directed to each input surface 42 of the second row of concentrators 16B. This is because the surfaces 38,40 of the sixth prism 34 are substantially the same shape, and the sixth prism 24 forms part of both fresnel optics 20A,20B.

This progressive light distribution also applies to the second fresnel optic 20B. As mentioned above, the sixth prism 34 is part of both fresnel optics 20A,20B, and the second fresnel optic 20B has several prisms 24,26,28,30,32,34 which function to provide a progressive light distribution in the same way as the prisms 24,26,28,30,32,34 of the first fresnel optic 20A. The prisms 24,26,28,30,32,34 on the left-hand side of the second fresnel optic 20B will be used to describe an example of the operation of the second fresnel optic 20B.

In this embodiment, sixty percent of the light from the fifth prism 32 the second fresnel optic 20B is directed to each input surface 42 of the second row of concentrators 16B, and forty percent of the light from the fifth prism 32 of the second fresnel optic 20B is directed to each input surface 42 of the first row of concentrators 16A. Seventy percent of the light from the fourth prism 30 of the second fresnel optic 20B is directed to each input surface 42 of the second row of concentrators 16B, and thirty percent of the light from the fourth prism 30 of the second fresnel optic 20B is directed to each input surface 42 of the first row of concentrators 16A. Eighty percent of the light from the third prism 28 of the second fresnel optic 20B is directed to each input surface 42 of the second row of concentrators 16B, and twenty percent of the light from the third prism 28 of the second fresnel optic 20B is directed to each input surface 42 of the first row of concentrators 16A. Ninety percent of the light from the second prism 26 of the second fresnel optic 20B is directed to each input surface 42 of the second row of concentrators 16B, and ten percent of the light from the second prism 26 of the second fresnel optic 20B is directed to each input surface 42 of the first row of concentrators 16A. Ninety-five percent of the light from the first prism 24 of the second fresnel optic 20B is directed to each input surface 42 of the second row of concentrators 16B, and five percent of the light from the first prism 24 of the second fresnel optic 20B is directed to each input surface 42 of the first row of concentrators 16A.

While the progressive light distribution from the prisms 24,26,28,30,32,34 has been described using the various percentages mentioned above, it is within the scope of the invention that the prisms 24,26,28,30,32,34 may be shaped differently to distribute the light between the input surfaces 42 of the respective concentrators 16 differently as desired. The percentage of light from the first fresnel optic 20A divided between the two rows of concentrators steadily increases until fifty percent is sent to each row of concentrators 16A,16B by the sixth prism 34, and then eventually all the light is sent to the second row of concentrators 16B by the arcuate portion 22 of the second fresnel optic 20B.

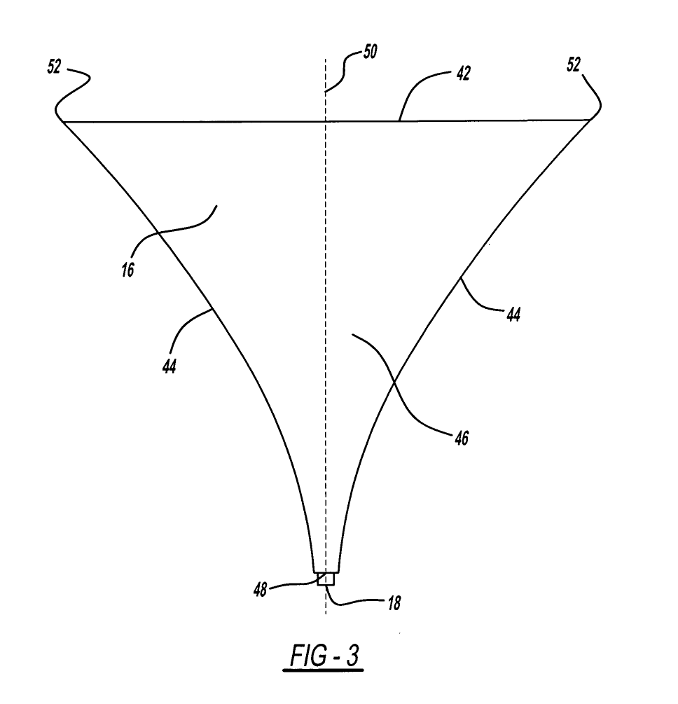

Referring now to FIG. 3, a side view of one of the concentrators 16 according to the present invention is shown. In addition to the input surface 42, each concentrator 16 also includes arcuate shaped side surfaces 44 which further act to concentrate the light received by the input surface 42 toward the photocell 18. Each side surface 42 has a hyperbolic profile, and each concentrator 16 has total internal reflection (TIR) properties to ensure that substantially all the light received by the input surface 42 is directed to the photocell 18. The outer surfaces 46 of the concentrator 16 are also substantially flat, and are substantially parallel to one another. The side surfaces 42 and the outer surfaces 46 terminate into an output surface 48 which is adjacent the photocell 18. Although the concentrator 16 is shown having the arcuate shaped side surfaces 44, it is within the scope of the invention that other shapes may be used to direct the light entering the input surface 42 to the photocell 18.

Each of the concentrators 16 has a focal line 50, and the focal line 50 extends through the input surface 42 of the concentrator 16 such that the focal line 50 passes through the concentrator 16 and the photocell 18. The focal line 50 also passes though the center of the arcuate portion 22 of the fresnel optic 20, best seen in FIG. 1.

As mentioned above, there are four rows of concentrators 16A,16B,16C,16D. In this embodiment, there are twelve concentrators in each row, best seen in FIG. 1. The amount of rows of concentrators 16A,16B,16C,16D can vary, depending upon the length and width of the optic 20. More specifically, the number of fresnel optics 20A,20B,20C,20D can be increased or decreased, and therefore, the number of rows of concentrators 16A,16B,16C,16D may be increased or decreased as well. Furthermore, the length of the fresnel optics 20A,20B,20C,20D may be increased, and more concentrators 16 may be added to each row 16A,16B,16C,16D. To facilitate maximizing efficiency, the concentrators 16 are positioned such that each edge 52 of the input surface 42 contacts the edge 52 of the adjacent concentrator 16. By way of example, the edge 52 of the input surface 42 of the first concentrator 16A1 contacts with the edge 52 of the input surface 42 of the next concentrator 16A2, as shown in FIG. 1.

In operation, the light entering the input surface 36 of each optic 20 is concentrated towards the input surface 42 of each concentrator 16 because of the shape of the optic 20, the light is further concentrated by the concentrator 16. More specifically, in this embodiment, the light entering the input surface 36 of the optic 20 is concentrated at a ratio of 50:1 because of the shape of each fresnel optic 20A,20B,20C,20D; therefore, the light entering the input surface 42 of each concentrator 16 receives light that is fifty times the intensity of the light entering the input surface 36. Furthermore, the light that enters the input surface 42 of one of the concentrators 16 is concentrated again at a ratio of 50:1 because of the shape of the concentrator 16; therefore, the light entering the photocell 18 is at fifty times the intensity of the light entering the input surface 42, and is at twenty-five hundred times (2500:1) the intensity of the light entering the input surface 36 of the optic 20.

The increase in intensity of the light passing through the optic 20 and the increase in intensity of the light each concentrator 16 produces a high-efficiency solar collector, and minimizes the amount of light lost to inefficiencies that may occur depending upon the shape of the prisms 24,26,28,30,32,34. More specifically, the shape of the arcuate surfaces 38 and the substantially straight surfaces 40, and the angle of the surfaces 38,40 relative to one another and to the other parts of the optic 20, such as the input surface 36, effects the efficiency of the optic 20. The optic 20 used in the system 10 of the present invention, and more specifically the prisms 24,26,28,30,32,34, are shaped such that the light from the prisms 24,26,28,30,32,34 and the arcuate portion 22 of the first fresnel optic 20A is directed to the concentrators 16 in the first row of concentrators 16A or the adjacent row of concentrators 16B as shown in FIG. 2, substantially reducing or eliminating any optical inefficiencies.

The optic 20 may be extruded clear glass (or clear acrylic plastic which is resistant to high temperatures). Extruding the optic 20 allows a large area of the optic 20 to be created, and then cut into sections of a desired size, facilitating ease of manufacture. The optic 20 may be cut to any length, with a greater or lesser amount of concentrators 16 used in each row. One of the sections of the optic 20 is shown in FIG. 1, and the section could also be used as a cover plate of the solar collector optic system 10. Each optical concentrator 16 is a cut and polished optical material plate glass or other suitable material.

The description of the invention is merely exemplary in nature and, thus, variations that do not depart from the essence of the invention are intended to be within the scope of the invention. Such variations are not to be regarded as a departure from the spirit and scope of the invention.

What is claimed is:

1. A solar collector comprising:
an optic, said optic including a first central portion;
a set of prisms configured to be parallel to said first central portion on a first lateral side thereof;
a second central portion configured parallel to said set of prisms on a second lateral side thereof; and
a first concentrator aligned with said first central portion and a second concentrator aligned with said second central portion;
wherein said set of prisms distributes light received between said first concentrator and said second concentrator in a predetermined ratio therebetween.

2. The solar collector of claim 1, wherein said set of prisms are operably configured to distribute light between said first concentrator and said second concentrator in a gradient manner based on the distance of each of said set of prisms from said first concentrator and said second concentrator.

3. The solar collector of claim 2, wherein said first central portion is a first elongate central portion including a convex lens for providing a focal point of said first concentrator, and said second central portion is a second elongate central portion including a convex lens for providing a focal point on said second concentrator.

4. The solar collector of claim 3, said first concentrator and said second concentrator further comprising a plurality of funnel-shaped flat concentrators which extend beneath said first elongate central portion and said second elongate central portion.

5. The solar collector of claim 2, wherein said set of prisms includes at least one prism element closer to said first concentrator that distributes a higher concentration of light to said first concentrator and a lower concentration of light to said second concentrator.

6. The solar collector of claim 5, wherein said set of prisms includes at least a second prism element which is closer to said second concentrator than said first concentrator, said second concentrator being configured for distributing a higher concentration of light to said second concentrator compared to said first concentrator.

7. The solar collector of claim 6, each prism element further comprising:
an arcuate surface; and
a straight surface, said arcuate surface and said straight surface forming a point facing away from the direction of light input into said optic for defining the light distribution to said first concentrator and said second concentrator.

8. The solar collector of claim 1, said optic further comprising a plurality of fresnel optics.

9. The solar collector of claim 8, wherein said plurality of fresnel optics are extruded as a single component.

10. The solar collector of claim 1, wherein said optic is made from one selected from the group consisting of an extruded clear glass and a clear acrylic plastic which is resistant to high temperatures.

11. The solar collector of claim 1, further comprising a plurality of photocells, one of said plurality of photocells operable with said first concentrator for receiving light from said first concentrator, and another of said plurality of photocells operable for receiving light from said second concentrator.

12. The solar collector of claim 11, further comprising each of said first concentrator and said second concentrator directing light to a corresponding one of said plurality of photocells through the use of total internal reflection.

13. The solar collector of claim 12, each of said first concentrator and said second concentrator further comprising:
an input surface for receiving light from said plurality of prisms;
at least one arcuate shaped side surface terminating into said input surface;
at least one outer surface terminating into said input surface; and
an output surface, said at least one arcuate surface and said at least one outer surface terminating into said output surface.

14. The solar collector of claim 13, said at least one arcuate shaped side surface further comprising a hyperbolic profile.

15. The solar collector of claim 13, wherein said output surface directs light to one of said plurality of photocells.

16. The solar collector of claim 11, further comprising one of said plurality of photocells and said first concentrator are in substantial alignment with a focal line extending through said first central portion, and one of said plurality of photocells and said second concentrator are in substantial alignment with a focal line extending through said second central portion.

17. The solar collector optics system of claim 1, wherein said optic concentrates light at a ratio of about fifty-to-one.

18. The solar collector optics system of claim 15, wherein each of said plurality of concentrators concentrates light at a ratio of about fifty-to-one, such that the combination of light passing through one of said optic and one of said first concentrator or said second concentrator is concentrated at a ratio of about twenty-five hundred-to-one.

19. The solar collector of claim 1, wherein said first concentrator and said second concentrator is made from a cut and polished optical glass material.

20. A solar collector optic system, comprising:
a plurality of optics having at least a first optic including a first central portion, and a second optic including a second central portion;
a first concentrator having a focal line, said focal line of said first concentrator aligned with said first central portion of said first optic;
a second concentrator having a focal line, said focal line of said second concentrator aligned with said second central portion of said second optic; and
a plurality of prisms for providing progressive light distribution to said first concentrator and said second concentrator, each of said first optic and said second optic having one or more of said plurality of prisms, such that as each of said plurality of prisms of said first optic is located further away from said focal line of said first concentrator, each of said plurality of prisms directs a greater amount of light to said second concentrator compared to said first concentrator, and as each of said plurality of prisms of said second optic is located further away from said focal line of said second concentrator, each of said plurality of prisms directs a greater amount of light to said first concentrator compared to said second concentrator.

21. The solar collector optics system of claim 20, said plurality of prisms further comprising:
at least a first prism formed as part of said first optic located next to said at least one arcuate portion, said first prism being shaped to direct a greater amount of light to said first concentrator compared to said second concentrator; and
at least a second prism formed as part of said first optic, said second prism being shaped to direct a lesser amount of light to said first concentrator compared to said first prism, and a greater amount of light to said second concentrator compared to said first prism.

22. The solar collector optics system of claim 21, further comprising a third prism, said third prism operable for directing a substantially equal amount of light to said first concentrator and said second concentrator.

23. The solar collector optics system of claim 21, wherein each of said plurality of prisms further comprising:
an arcuate surface, each of said arcuate surface of each of said plurality of prisms being shaped differently; and
a substantially straight surface terminating into said arcuate surface, such that that shape of said arcuate surface and the angle of said arcuate surface relative to said substantially straight surface controls the amount of light directed to said first concentrator and said second concentrator.

24. The solar collector optics system of claim 20, wherein each of said first optic and said second optic further comprising a plurality of fresnel optics.

25. The solar collector optics system of claim 24, wherein said plurality of fresnel optics are extruded as a single component.

26. The solar collector optics system of claim 20, wherein each of said first optic and said second optic is made from a material selected from the group consisting of an extruded clear glass, a clear acrylic plastic which is resistant to high temperatures, and mixtures thereof.

27. The solar collector optics system of claim 20, further comprising:
a plurality of first and second concentrators aligned with said first and second central portions; and
a plurality of photocells, each one of said plurality of photocells operable with a respective one of said plurality of concentrators for receiving light from each one of said plurality of first and second concentrators.

28. The solar collector optics system of claim 27, further comprising each of said plurality of concentrators directing light to one of said plurality of photocells through the use of total internal reflection.

29. The solar collector optic system of claim 27, each of said plurality of concentrators further comprising:
an input surface for receiving light from said plurality of prisms;
at least one arcuate shaped side surface terminating into said input surface;
at least one outer surface terminating into said input surface; and
an output surface, said at least one arcuate surface and said at least one outer surface terminating into said output surface.

30. The solar collector optics system of claim 29, said at least one arcuate shaped side surface further comprising a hyperbolic profile.

31. The solar collector optics system of claim 29, wherein said output surface directs light to one of said plurality of photocells.

32. The solar collector optics system of claim 27, further comprising one of said plurality of photocells and a corresponding one of said plurality of concentrators are in substantial alignment with said focal line extending through said at least one arcuate portion formed as part of one of said plurality of optics.

33. The solar collector optics system of claim 20, wherein each of said plurality of optics concentrates light at a ratio of about fifty-to-one.

34. The solar collector optics system of claim 33, wherein each of said plurality of concentrators concentrates light at a ratio of about fifty-to-one, such that the combination of light passing through one of said plurality of optics and one of said plurality of concentrators is concentrated at a ratio of about twenty-five hundred-to-one.

35. The solar collector optics system of claim 20, wherein each concentrator is made from a cut and polished optical glass material.

36. A solar collector optics system, comprising:
a first fresnel optic having an input surface such that light passes through said first fresnel optic;
a second fresnel optic an input surface such that light passes through said second fresnel optic;
a first concentrator having a focal line, said first concentrator for receiving light from said first fresnel optic and said second fresnel optic;
a second concentrator having a focal line, said second concentrator for receiving light from said first fresnel optic and said second fresnel optic;
a first plurality of prisms formed as part of said first fresnel optic, said first plurality of prisms direct light passing through said first fresnel optic to said first concentrator and said second concentrator;
a second plurality of prisms formed as part of said second fresnel optic, said second plurality of prisms direct light passing through said second fresnel optic to said first concentrator and said second concentrator; and
a plurality of photocells, one of said plurality photocells is positioned adjacent to and in contact with said first concentrator such that said at least one photocell receives substantially all of the light passing through said first concentrator, and another of said plurality of photocells is positioned adjacent to and in contact with said second concentrator such that said at least one photocell receives substantially all of the light passing through said second concentrator;
wherein said first plurality of prisms has a progressive light distribution function such that said portion of said first plurality of prisms are adjacent one another and progressively distribute light in greater amounts to said second concentrator relative to said first concentrator the further each of said first plurality of prisms formed are away from said focal line of said first concentrator, and said second plurality of prisms has a progressive light distribution function such that said portion of said second plurality of prisms are adjacent one another and progressively distribute light in greater amounts to said first concentrator relative to said second concentrator the further each of said second plurality of prisms formed are away from said focal line of said second concentrator.

37. A method for directing light to a plurality of concentrators in a solar collector optics system, comprising the steps of:
providing a plurality of optics having at least a first optic and at least a second optic;
providing a plurality of concentrators arranged in one or more rows, each of said plurality of concentrators having a focal line extending through one of said plurality of optics;
providing a plurality of prisms formed as part of said first optic positioned adjacent one another in a consecutive manner for progressively distributing light between a first row of concentrators and a second row of concentrators;
providing a plurality of prisms formed as part of said second optic positioned adjacent one another in a consecutive manner for progressively distributing light between said first row of concentrators and said second row of concentrators;
forming a first row of concentrators using a portion of said plurality of concentrators;
forming a second row of concentrators using a portion of said plurality of optics;
directing a portion of light passing through said plurality of prisms formed as part of said first optic to said first row of concentrators and said second row of concentrators with said plurality of prisms formed as part of said first optic; and
directing a portion of light passing through said plurality of prisms formed as part of said second optic to said first row of concentrators and said second row of concentrators with said plurality of prisms formed as part of said second optic.

38. The method for directing light to a plurality of concentrators in a solar collector optics system of claim 37, further comprising the steps of providing an arcuate portion formed as part of each of said plurality of optics, said focal line from each of said plurality of concentrators extending through said arcuate portion of one of said plurality of optics.

39. The method for directing light to a plurality of concentrators in a solar collector optics system of claim 38, each of said plurality of prisms formed as part of each of said plurality of optics are further comprised of:
providing a first prism located next to said at least one arcuate portion, said first prism being shaped to direct a greater amount of light to said first row of concentrators compared to said second row of concentrators;
providing a second prism formed as part of one of said plurality of optics such that said first prism is between said second prism and said arcuate portion, said second prism being shaped to direct a lesser amount of light to said first row of concentrators compared to said first prism, and a greater amount of light to said second row of concentrators compared to said first prism;
providing a third prism formed as part of said one of said plurality of optics such that second prism is between said first prism and said third prism, said third prism being shaped to direct a lesser amount of light to said first row of concentrators compared to said second prism, and a greater amount of light to said second row of concentrators compared to said second prism;
providing a fourth prism formed as part of one of said plurality of optics such that said third prism is between said second prism and said fourth prism, said fourth prism being shaped to direct a lesser amount of light to said first row of concentrators compared to said third prism, and a greater amount of light to said second row of concentrators compared to said third prism;
providing a fifth prism formed as part of said one of said plurality of optics such that said fourth prism is between said third prism and said fifth prism, said fifth prism being shaped to direct a lesser amount of light to said first row of concentrators compared to said fourth prism, and a greater amount of light to said second row of concentrators compared to said fourth prism; and
providing a sixth prism form as part of two of said plurality of optics, said sixth prism operable for directing a substantially equal amount of light to said first row of concentrators and said second row of concentrators.

40. The method for directing light to a plurality of concentrators in a solar collector optics system of claim 39, further comprising the steps of providing each of said plurality of prisms to be comprised of:
providing an arcuate surface; and
providing a substantially straight surface connected to said arcuate surface; and
positioning said arcuate surface and said substantially straight surface to direct light towards said first row of concentrators and said second row of concentrators;
controlling the amount of light directed to said first row of concentrators and said second row of concentrators by the angle and shape of said arcuate surface, and the angle and shape of said substantially straight surface.

41. The method for directing light to a plurality of concentrators in a solar collector optics system of claim 37, providing each of said plurality of concentrators to be further comprised of:
providing an input surface for receiving light from said plurality of prisms formed as part of said first optic and said plurality of prisms formed as part of said second optic;
providing at least one arcuate shaped side surface having a hyperbolic profile;
providing at least one outer surface; and
providing an output surface, said at least one arcuate surface and said at least one outer surface terminate in said output surface;
directing light received by said first plurality of prisms and said second plurality of prisms to said output surface with said arcuate shaped side surface.

42. The method for directing light to a plurality of concentrators in a solar collector optics system of claim 41, further comprising the steps of:
providing a plurality of photocells; and
positioning one of said plurality of photocells to be in contact with said output surface formed as part of one of said plurality of concentrators such that said one of said plurality of photocells receives light from said one of said plurality of concentrators.

43. The method for directing light to a plurality of concentrators in a solar collector optics system of claim 42, further comprising the steps of directing light to said plurality of photocells with each of said plurality of concentrators through the use of total internal reflection.

44. The method for directing light to a plurality of concentrators in a solar collector optics system of claim 37, further comprising the steps of aligning one of said plurality of photocells with said focal line of a respective one of said plurality of concentrators.

45. The method for directing light to a plurality of concentrators in a solar collector optics system of claim 37, further comprising the steps of making each of said plurality of concentrators from a cut and polished optical glass material.

46. The method for directing light to a plurality of concentrators in a solar collector optics system of claim 37, further comprising the steps of making each of said plurality of optics from a material selected from the group consisting of an extruded clear glass, a clear acrylic plastic which is resistance to high temperatures, and mixtures thereof.

47. The method for directing light to a plurality of concentrators in a solar collector optics system of claim 37, further comprising the steps of providing each of said plurality of optics to be a fresnel optic.

48. The method for directing light to a plurality of concentrators in a solar collector optics system of claim 37, further comprising the steps of extruding said plurality of optics as a single component.
